(19) United States
(12) Patent Application Publication
(10) Pub. No.: US 2025/0316461 A1
(43) Pub. Date: Oct. 9, 2025

(54) PLASMA PROCESSING APPARATUS AND CONTROL METHOD

(71) Applicant: Tokyo Electron Limited, Tokyo (JP)

(72) Inventor: Masato TAKAYAMA, Miyagi (JP)

(73) Assignee: Tokyo Electron Limited, Tokyo (JP)

(21) Appl. No.: 19/241,448

(22) Filed: Jun. 18, 2025

Related U.S. Application Data
(63) Continuation of application No. PCT/JP2023/043835, filed on Dec. 7, 2023.

(30) Foreign Application Priority Data
Dec. 21, 2022 (JP) 2022-204826

(51) Int. Cl. H01J 37/32; H01L 21/683

(52) U.S. Cl. CPC H01J 37/32715; H01J 37/32642; H01L 21/6833; H01J 2237/002; H01J 2237/2007; H01J 2237/3343

(57) ABSTRACT

A pedestal is disposed in a plasma processing chamber and has a flow path inside for a heat transfer medium. A temperature adjuster circulates the heat transfer medium through the flow path and regulates the temperature of the heat transfer medium. An electrostatic chuck on an upper surface of the pedestal has a substrate placing portion and an edge ring placing portion that surrounds a substrate, a first electrostatic electrode layer is disposed on the substrate placing portion and a second electrostatic electrode layer is disposed on the edge ring placing portion. An adsorptive sheet is disposed at least one of between the substrate placing portion and the substrate or between the edge ring placing portion and the edge ring, and changes in adhesive strength by changing temperature.

### CROSS-REFERENCE TO RELATED APPLICATIONS

This application is a continuation application of International Application PCT/JP2023/043835, filed on Dec. 7, 2023, and designating the U.S., which claims priority to Japanese Patent Application No. 2022-204826, filed on Dec. 21, 2022, the entire contents of each of which are incorporated herein by reference.

### FIELD

Exemplary embodiments disclosed herein relate to a plasma processing apparatus and a control method.

### BACKGROUND

Patent Literature 1 below discloses “a plasma processing apparatus comprising: a focus ring installed outside a substrate mounted on a mounting table including a temperature control mechanism, and configured to be in contact with the mounting table via a heat transfer sheet, wherein a heat insulating layer having a heat conductivity lower than that of the focus ring is provided on a surface of the focus ring at a side of the heat transfer sheet among the surfaces of the focus ring.”.

Patent Literature 2 below discloses “a stage comprising: an electrostatic chuck configured to support a substrate and an edge ring; and a base configured to support the electrostatic chuck, wherein the electrostatic chuck includes: a first region having a first upper surface and configured to support the substrate placed on the first upper surface; a second region having a second upper surface, provided integrally around the first region, and configured to support the edge ring placed on the second upper surface; a first electrode provided in the first region and configured to apply a DC voltage; a second electrode provided in the second region and configured to apply a DC voltage; and a third electrode configured to apply a bias power.”.

Patent Literature 1: Japanese Patent Application Laid-open No. 2016-39344

Patent Literature 2: Japanese Patent Application Laid-open No. 2020-205379

### SUMMARY

In an embodiment of a present disclosure, a plasma processing apparatus comprising: a plasma processing chamber; a pedestal disposed in the plasma processing chamber and configured such that a flow path for a heat transfer medium is formed inside; a temperature adjuster configured to circulate the heat transfer medium through the flow path and to regulate a temperature of the heat transfer medium; an electrostatic chuck disposed on an upper surface of the pedestal and configured to have a substrate placing portion on which a substrate is placed and an edge ring placing portion on which an edge ring surrounding the substrate is placed; a first electrostatic electrode layer configured to be disposed in the substrate placing portion; a second electrostatic electrode layer configured to be disposed in the edge ring placing portion; a first power supply configured to be electrically connected to the first electrostatic electrode layer; a second power supply configured to be electrically connected to the second electrostatic electrode layer; and an adsorptive sheet disposed at least one of between the substrate placing portion and the substrate placed on the substrate placing portion, or between the edge ring placing portion and the edge ring placed on the edge ring placing portion, and configured to change in adhesive strength by changing temperature.

### BRIEF DESCRIPTION OF DRAWINGS

FIG. 1 is a diagram illustrating a configuration example of a capacitively coupled plasma processing apparatus.

FIG. 2 is a diagram illustrating an example of a configuration of a substrate support.

FIG. 3A is a graph illustrating an example of change in adhesive strength of an adsorptive sheet.

FIG. 3B is a diagram illustrating an example of adhesion of an object by the adsorptive sheet.

FIG. 4A is a diagram illustrating an example of an annular adsorptive sheet which is cut out in a plurality of separate regions.

FIG. 4B is a diagram illustrating an example of an annular adsorptive sheet which is cut out in a plurality of separate regions.

FIG. 5 is a diagram illustrating improvement in heat conductivity of a ring assembly according to an embodiment.

FIG. 6 is a diagram illustrating improvement in heat conductivity of a substrate W according to an embodiment.

FIG. 7 is a diagram schematically illustrating an example of a configuration of a conventional substrate support.

FIG. 8 is a flowchart illustrating an example of a control process flow including processing of a control method according to an embodiment.

FIG. 9A is a diagram schematically illustrating an example of a flow of holding a ring assembly.

FIG. 9B is a graph illustrating an example of temperature change in the adsorptive sheet.

FIG. 10 is a diagram illustrating an example of a schematic configuration around a ceiling at an upper part of a plasma processing chamber.

### DESCRIPTION OF EMBODIMENT

Embodiments of a plasma processing apparatus and a control method will be described in detail below based on the drawings. The plasma processing apparatus and the control method disclosed herein are not limited by the following embodiments.

Conventionally, a plasma processing apparatus for performing plasma processing on a substrate such as a semiconductor wafer (hereinafter also referred to as “wafer”) has been known. In the plasma processing apparatus, a placing pedestal on which a substrate is placed is provided inside a vacuum chamber. An edge ring such as a focus ring is disposed on the placing pedestal so as to surround the outer periphery of the substrate. The edge ring expands a distribution area of plasma generated above the substrate not only onto the substrate but also onto the edge ring to ensure uniformity of etching and other processing performed on the entire substrate surface.

Since the substrate and the edge ring are directly exposed to the plasma, their temperature rises due to heat input from the plasma. Therefore, in the plasma processing apparatus, technology to improve a heat transfer rate between at least one of the substrate and the edge ring and the placing pedestal is expected in order to diffuse the heat of the substrate and the edge ring toward the placing pedestal.

### Embodiment

### [Apparatus Configuration]

An example of a plasma processing apparatus disclosed herein will be described. In embodiments described below, the plasma processing apparatus disclosed herein is described as a plasma processing system in a system configuration by way of example.

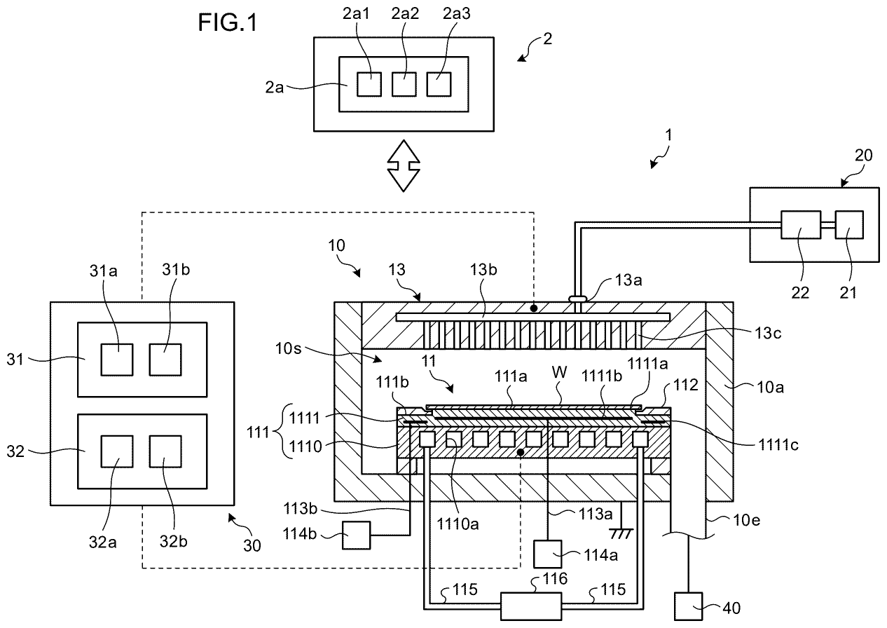

A configuration example of a plasma processing system will be described below. FIG. 1 is a diagram illustrating a configuration example of a capacitively coupled plasma processing apparatus.

The plasma processing system includes a capacitively coupled plasma processing apparatus 1 and a controller 2. The capacitively coupled plasma processing apparatus 1 includes a plasma processing chamber 10, a gas supply unit 20, a power supply 30, and an exhaust system 40. The plasma processing apparatus 1 also includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s and at least one gas discharge port for discharging the gas from the plasma processing space. The plasma processing chamber 10 is grounded. The shower head 13 and the substrate support 11 are electrically insulated from a housing of the plasma processing chamber 10. The functionality of the elements disclosed herein may be implemented using circuitry or processing circuitry which includes general purpose processors, special purpose processors, integrated circuits, ASICs (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The substrate support 11 includes a body 111 and a ring assembly 112. The body 111 has a central region 111a for supporting a substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 so as to surround the substrate W on the central region 111a of the body 111. Thus, the central region 111a is also referred to as substrate support surface for supporting the substrate W, and the annular region 111b is also referred to as ring support surface for supporting the ring assembly 112.

In one embodiment, the body 111 includes a pedestal 1110 and an electrostatic chuck 1111. The pedestal 1110 includes a conductive member. The conductive member of the pedestal 1110 can function as a lower electrode. The electrostatic chuck 1111 is disposed on the pedestal 1110. The electrostatic chuck 1111 includes a ceramic member 1111a and electrostatic electrodes 1111b and 1111c disposed in the ceramic member 1111a. The ceramic member 1111a has the central region 111a. In one embodiment, the ceramic member 1111a also has the annular region 111b. The electrostatic electrode 1111b is disposed in a central region 111a portion in the ceramic member 1111a. The electrostatic electrode 1111c is disposed in an annular region 111b portion in the ceramic member 1111a. The electrostatic electrode 1111b is connected to a DC power supply 114a via wiring 113a. The electrostatic electrode 1111c is connected to a DC power supply 114b via wiring 113b. The electrostatic electrodes 1111b and 1111c are configured such that a DC voltage can be applied from the DC power supplies 114a and 114b, respectively. The DC power supplies 114a and 114b may be configured as a single DC power supply. Another member that surrounds the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Furthermore, at least one RF/DC electrode coupled to a radio frequency (RF) power supply 31 and/or a direct current (DC) power supply 32, which will be described below, may be disposed in the ceramic member 1111a. In this case, at least one RF/DC electrode functions as a lower electrode. When a bias RF signal and/or a DC signal described later is supplied to at least one RF/DC electrode, the RF/DC electrode is also referred to as bias electrode. The conductive member of the pedestal 1110 and at least one RF/DC electrode may function as a plurality of lower electrodes. The electrostatic electrode 1111b may function as a lower electrode. Thus, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 may include a temperature adjusting module configured to adjust at least one of the electrostatic chuck 1111, the ring assembly 112, and the substrate to a target temperature. The temperature adjusting module may include a heater, a heat transfer medium, a flow path 1110a, or a combination thereof. A heat transfer fluid such as brine or gas flows through the flow path 1110a. In one embodiment, the flow path 1110a is formed in the pedestal 1110, and one or more heaters are disposed in the ceramic member 1111a of the electrostatic chuck 1111. Both ends of the flow path 1110a are connected to a temperature adjusting unit 116 via respective pipes 115. The temperature adjusting unit 116 circulates a heat transfer medium that can be used for temperature adjustment, such as a heat transfer fluid, through the flow path 1110a via the pipes 115. The temperature adjusting unit 116 can control the temperature of the heat transfer medium by control from the controller 2 described later. The heat transfer medium supplied by the temperature adjusting unit 116 circulates through the flow path 1110a and the pipes 115 to regulate the temperature of the body 111. In the present embodiment, the pipes 115 and the temperature adjusting unit 116 correspond to a temperature adjuster in the present disclosure.

The shower head 13 is configured to introduce at least one processing gas from the gas supply unit 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s through the gas introduction ports 13c. The shower head 13 includes at least one upper electrode. In addition to the shower head 13, the gas introduction unit may include one or more side gas injectors (SGI) that are attached to one or more openings formed in the side wall 10a.

The gas supply unit 20 may include at least one gas source 21 and at least one flow controller 22. In one embodiment, the gas supply unit 20 is configured to supply at least one processing gas from respective corresponding gas sources 21 to the shower head 13 through respective corresponding flow controllers 22. Each of the flow controllers 22 may include, for example, a mass flow controller or a pressure-controlled flow controller. In addition, the gas supply unit 20 may include one or more flow modulation devices that modulate or pulse the flow volume of at least one processing gas.

The power supply 30 includes the RF power supply 31 coupled to the plasma processing chamber 10 through at least one impedance matching circuit. The RF power supply 31 is configured to supply at least one RF signal (RF power) to at least one lower electrode and/or at least one upper electrode. Thus, plasma is formed from at least one processing gas supplied to the plasma processing space 10s. Accordingly, the RF power supply 31 can function as at least a part of a plasma generator configured to generate plasma from one or more processing gases in the plasma processing chamber 10. Furthermore, a bias RF signal is supplied to at least one lower electrode to generate a bias potential in the substrate W, so that ion components in the formed plasma can be drawn into the substrate W.

In one embodiment, the RF power supply 31 includes a first RF generator 31a and a second RF generator 31b. The first RF generator 31a is coupled to at least one lower electrode and/or at least one upper electrode through at least one impedance matching circuit and configured to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to at least one lower electrode through at least one impedance matching circuit and configured to generate a bias RF signal (bias RF power). The frequency of the bias RF signal may be the same as or different from the frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

Furthermore, the power supply 30 may include a DC power supply 32 coupled to the plasma processing chamber 10. The DC power supply 32 includes a first DC generator 32a and a second DC generator 32b. In one embodiment, the first DC generator 32a is connected to at least one lower electrode and configured to generate a first DC signal. The generated first bias DC signal is applied to at least one lower electrode. In one embodiment, the second DC generator 32b is connected to at least one upper electrode and configured to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform such as rectangle, trapezoid, triangle, or a combination thereof. In one embodiment, a waveform generator for generating a sequence of voltage pulses from a DC signal is connected between the first DC generator 32a and at least one lower electrode. Accordingly, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have a positive polarity or a negative polarity. Furthermore, the sequence of voltage pulses may include one or more positive voltage pulses and one or more negative voltage pulses in one cycle. The first and second DC generators 32a and 32b may be provided in addition to the RF power supply 31, or the first DC generator 32a may be provided instead of the second RF generator 31b.

The exhaust system 40 may be connected, for example, to a gas discharge port 10e provided at the bottom of the plasma processing chamber 10. The exhaust system 40 may include a pressure regulating valve and a vacuum pump. The pressure in the plasma processing space 10s is regulated by the pressure regulating valve. The vacuum pump may include a turbomolecular pump, a dry pump, or a combination thereof.

The controller 2 processes computer-executable instructions that cause the plasma processing apparatus 1 to perform various processes described in the present disclosure. The controller 2 can be configured to control each element of the plasma processing apparatus 1 to perform various processes described herein. In one embodiment, a part or all of the controller 2 may be included in the plasma processing apparatus 1. The controller 2 may include a processing unit 2a1, a storage 2a2, and a communication interface 2a3. The controller 2 is implemented, for example, by a computer 2a. The processing unit 2a1 can be configured to perform various control operations by reading a computer program from the storage 2a2 and executing the read computer program. The computer program may be stored in the storage 2a2 in advance or may be obtained via a medium when needed. The obtained computer program is stored into the storage 2a2 and read from the storage 2a2 by the processing unit 2a1 for execution. The medium may be various storage media readable by the computer 2a or a communication line connected to the communication interface 2a3. The processing unit 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

The operation of the plasma processing apparatus 1 configured as described above is centrally controlled by the controller 2 described above.

The controller 2 controls plasma etching. For example, the controller 2 controls the exhaust system 40 to evacuate the plasma processing chamber 10 to a predetermined vacuum level. The controller 2 controls the gas supply unit 20 to introduce processing gas for etching from the gas supply unit 20 into the plasma processing space 10s. The controller 2 controls the power supply 30 to supply power from the power supply 30 to generate plasma in the plasma processing chamber 10 and perform etching on the substrate W in accordance with the introduction of processing gas. Since the substrate W and the ring assembly 112 are directly exposed to the plasma, their temperature rises due to heat input from the plasma.

In the plasma processing apparatus 1 according to the present embodiment, the substrate support 11 is configured as follows in order to efficiently diffuse heat of the substrate W and the ring assembly 112 toward the body 111.

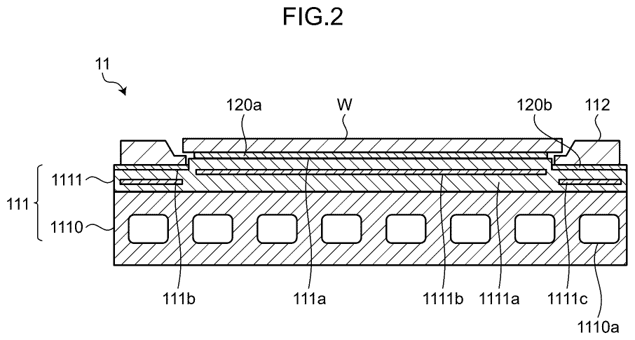

FIG. 2 is a diagram illustrating an example of a configuration of the substrate support 11. FIG. 2 schematically illustrates a configuration of the body 111 of the substrate support 11. The substrate support 11 includes the body 111 and the ring assembly 112. The body 111 includes the pedestal 1110 and the electrostatic chuck 1111.

In the central region 111a of the electrostatic chuck 1111, an adsorptive sheet 120a is disposed and the substrate W is placed on the adsorptive sheet 120a. In the annular region 111b of the electrostatic chuck 1111, an adsorptive sheet 120b is disposed and the ring assembly 112 is placed on the adsorptive sheet 120a. The pedestal 1110 is configured such that the flow path 1110a is formed in a region that overlaps at least partially with a region where the adsorptive sheets 120a and 120b are disposed in a plan view.

The adsorptive sheets 120a and 120b are configured to change in adhesive strength by changing temperature. For example, the adsorptive sheets 120a and 120b are formed of thermosensitive adhesive sheets, and their adhesive strength changes in a first temperature range and in a second temperature range above the first temperature range. Examples of such a thermosensitive adhesive sheet include Intelimer (registered trademark) tape from Nitta Corporation. The thermosensitive adhesive sheet has a switching temperature at which the adhesive strength switches, and the adhesive strength changes significantly in the first temperature range below the switching temperature and in the second temperature range above the switching temperature. The switching temperature can be regulated by a material contained in the thermosensitive adhesive sheet. The thermosensitive adhesive sheet includes a cool-off type and a warm-off type. In the cool-off type, adhesive strength decreases in the first temperature range and adhesive strength increases in the second temperature range. In the warm-off type, adhesive strength increases in the first temperature range and adhesive strength decreases in the second temperature range.

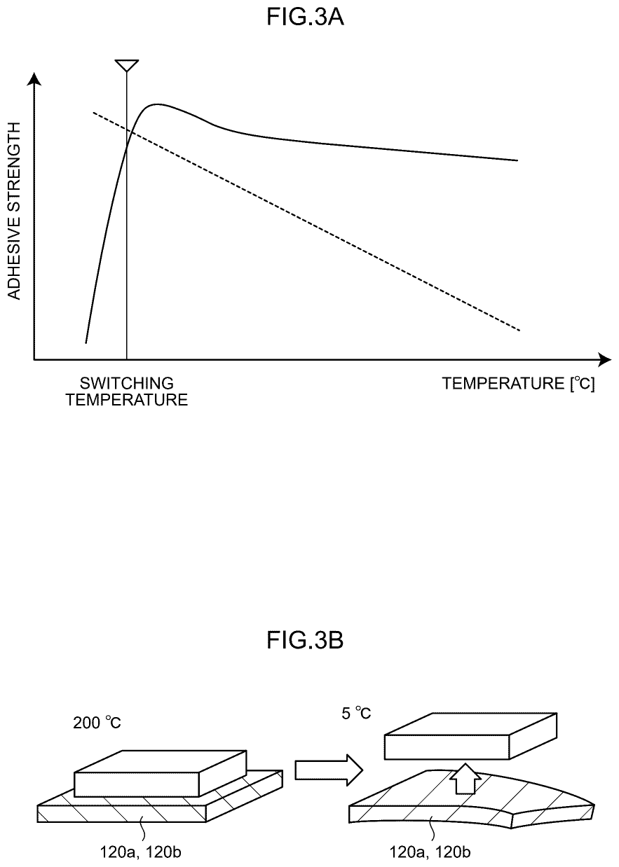

In the present embodiment, it is assumed that the adsorptive sheets 120a and 120b are the cool-off type, and the adhesive strength increases in the second temperature range above the first temperature range. FIG. 3A is a graph illustrating an example of change in adhesive strength of the adsorptive sheets 120a and 120b. The adsorptive sheets 120a and 120b have adhesive strength decreasing in the first temperature range below the switching temperature and increasing in the second temperature range above the switching temperature. The switching temperature is, for example, 50° C. FIG. 3B is a diagram illustrating an example of change in adhesion of an object by the adsorptive sheets 120a and 120b. For example, when the adsorptive sheets 120a and 120b have a temperature in the first temperature range (e.g., 70° C. to 200° C.), the adsorption becomes strong and the placed object can be held. On the other hand, when the adsorptive sheets 120a and 120b have a temperature in the second temperature range (e.g., 30° C. or lower), the adsorption becomes weak and the placed object can be easily peeled off.

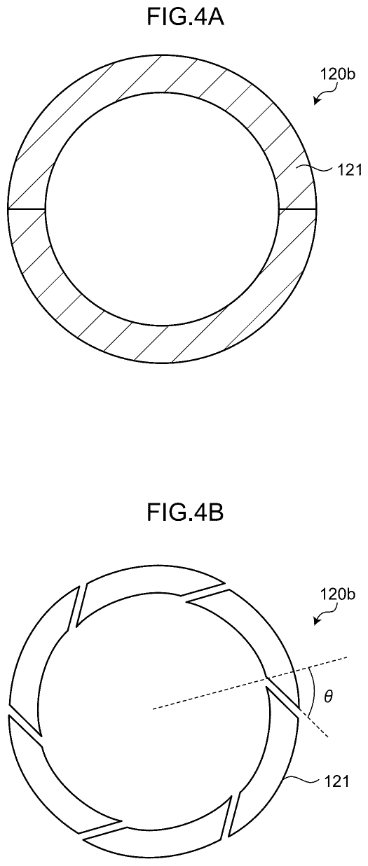

The adsorptive sheet 120a is formed in a circular shape to be disposed in the central region 111a. The adsorptive sheet 120b is formed in an annular shape to be disposed in the annular region 111b. When such a circular adsorptive sheet 120a or annular adsorptive sheet 120b is cut out of the thermosensitive adhesive sheet serving as the base material, with no slits, the large size to be cut out may prevent effective use of the remaining region of the thermosensitive adhesive sheet serving as the base material. Thus, the adsorptive sheets 120a and 120b each may be cut out of the thermosensitive adhesive sheet in a plurality of separate regions. In this case, since a smaller size is cut out of the thermosensitive adhesive sheet serving as the base material, the remaining region of the thermosensitive adhesive sheet serving as the base material is larger, so that the number of thermosensitive adhesive sheets to be cut out can be increased, and the thermosensitive adhesive sheet serving as the base material can be used effectively. FIG. 4A and FIG. 4B are diagrams illustrating an example of the annular adsorptive sheet 120b which is cut out in a plurality of separate regions. In FIG. 4A and FIG. 4B, sheets 121 in a plurality of separate arc-shaped regions are cut out, and the sheets 121 are arranged in an annular pattern to form the annular adsorptive sheet 120b. For example, in FIG. 4A, two sheets 121 in semicircular arc-shaped regions are separately cut out, and the two sheets 121 are arranged in an annular pattern to form the annular adsorptive sheet 120b. In FIG. 4B, the sheets 121 in six arc-shaped partial regions are separately cut out, and the six sheets 121 are arranged in an annular pattern to form the annular adsorptive sheet 120b. The arc-shaped sheets 121 can be lined up in the same direction to be cut out of a single thermosensitive adhesive sheet. This can reduce a wasted region that cannot be used for the adsorptive sheet 120b. A gap between the sheets 121 is likely to be a temperature singularity. Thus, the gap between the sheets 121 is preferably 2 mm or less. In the adsorptive sheet 120b, preferably, the sheets 121 are cut out such that a linear gap is formed between the arc-shaped sheets 121 and the angle θ of the gap between the sheets 121 is 30° to 60° relative to the radial direction of the adsorptive sheet 120b. The adsorptive sheet 120b is thus configured such that the gap is oriented 30° to 60° relative to the radial direction of the ring assembly 112. As a result, in the adsorptive sheet 120b, the effect of the temperature singularity due to the gap between the sheets 121 can be reduced.

The description returns to FIG. 2. The adsorptive sheets 120a and 120b are each configured such that its lower surface is bonded to the electrostatic chuck 1111 and its upper surface has adhesive strength increased by changing temperature in a range lower than adhesive strength by bonding on the lower surface side. For example, the adsorptive sheets 120a and 120b each include a plurality of layers, in which the upper surface layer is composed of a cool-off type thermosensitive adhesive sheet and the lower surface layer is composed of a bonding layer having adhesive strength larger than adhesive strength in the second temperature range of the thermosensitive adhesive sheet.

The electrostatic chuck 1111 has the electrostatic electrode 1111b inside the central region 111a portion and the electrostatic electrode 1111c inside the annular region 111b portion. A DC voltage is applied to the electrostatic electrodes 1111b and 1111c from the DC power supplies 114a and 114b in accordance with the control of the controller 2.

The description returns to FIG. 1. The controller 2 controls the temperature of the substrate support 11 by controlling the temperature adjusting unit 116, controlling the temperature of the heat transfer medium supplied from the temperature adjusting unit 116, and circulating the heat transfer medium through the flow path 1110a and the pipes 115.

The controller 2 controls the temperature of the heat transfer medium by the temperature adjusting unit 116 so that the adhesive strength of the adsorptive sheets 120a and 120b increases when plasma processing is performed in the plasma processing chamber 10. For example, the controller 2 controls the temperature of the heat transfer medium supplied from the temperature adjusting unit 116 so that the temperature of the substrate support 11 falls within the second temperature range. The controller 2 then controls the DC power supplies 114a and 114b to apply a DC voltage of a predetermined voltage as a clamping voltage from the DC power supply 114a to the electrostatic electrode 1111b, and apply a DC voltage of a predetermined voltage as a clamping voltage from the DC power supply 114b to the electrostatic electrode 1111c.

When at least one of the substrate W and the ring assembly 112 is replaced, the controller 2 controls the temperature of the heat transfer medium by the temperature adjusting unit 116 so that the adhesive strength of the adsorptive sheets 120a and 120b decreases. For example, the controller 2 controls the temperature of the heat transfer medium supplied from the temperature adjusting unit 116 so that the temperature of the substrate support 11 falls within the first temperature range. The controller 2 then controls the DC power supplies 114a and 114b to stop the application of a DC voltage from the DC power supplies 114a and 114b to the electrostatic electrodes 1111b and 1111c.

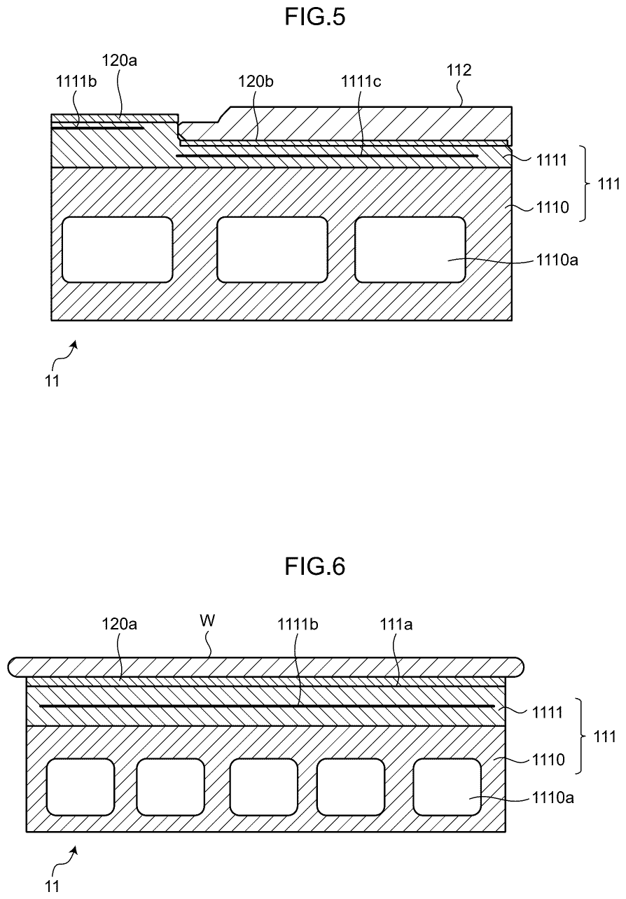

FIG. 5 illustrates improvement in heat conductivity of the ring assembly 112 according to an embodiment. FIG. 5 schematically illustrates a configuration of a portion of the substrate support 11 on which the ring assembly 112 is placed.

When the temperature of the substrate support 11 is set to the second temperature range during plasma processing, the adsorptive sheet 120b increases its adsorption strength and strongly holds the ring assembly 112. Furthermore, when a DC voltage is applied to the electrostatic electrode 1111c, the ring assembly 112 is electrostatically clamped to the electrostatic chuck 1111. Thus, the ring assembly 112 comes into close contact with the adsorptive sheet 120b. The close contact of the ring assembly 112 with the adsorptive sheet 120b lowers the interface thermal resistance between the ring assembly 112 and the adsorptive sheet 120b. Thus, the heat conductivity between the ring assembly 112 and the body 111 can be improved. As a result, the ring assembly 112 can efficiently diffuse the heat input from plasma toward the body 111.

On the other hand, when the temperature of the substrate support 11 is set to the first temperature range during replacement of at least one of the substrate W and the ring assembly 112, the adsorptive sheet 120b decreases its adsorption strength. Furthermore, when the application of a DC voltage to the electrostatic electrode 1111c stops, the ring assembly 112 is no longer electrostatically clamped to the electrostatic chuck 1111. As a result, the ring assembly 112 can be easily peeled off from the body 111.

FIG. 6 is a diagram illustrating improvement in heat conductivity of the substrate W according to an embodiment. FIG. 6 schematically illustrates a configuration of a portion of the substrate support 11 on which the substrate W is placed.

When the temperature of the substrate support 11 is set to the second temperature range during plasma processing, the adsorptive sheet 120a increases its adsorption strength and strongly holds the substrate W. Furthermore, when a DC voltage is applied to the electrostatic electrode 1111b, the substrate W is electrostatically clamped to the electrostatic chuck 1111. Thus, the substrate W comes into close contact with the adsorptive sheet 120a. The close contact of the substrate W with the adsorptive sheet 120a lowers the interface thermal resistance between the substrate W and the adsorptive sheet 120a. Thus, the heat conductivity between the substrate W and the body 111 can be improved. As a result, the substrate W can efficiently diffuse the heat input from plasma toward the body 111.

On the other hand, when the temperature of the substrate support 11 is set to the first temperature range during replacement of at least one of the substrate W and the ring assembly 112, the adsorptive sheet 120a decreases its adsorption strength. Furthermore, when the application of a DC voltage to the electrostatic electrode 1111b stops, the substrate W is no longer electrostatically clamped to the electrostatic chuck 1111. As a result, the substrate W can be easily peeled off from the body 111.

As a comparative example, an example of the configuration of a conventional plasma processing apparatus will now be described. In the conventional plasma processing apparatus, helium (He) gas is supplied as a heat transfer gas between the substrate W and ring assembly 112 and the electrostatic chuck 1111 in order to improve a heat transfer rate between the substrate W and ring assembly 112 and the body 111.

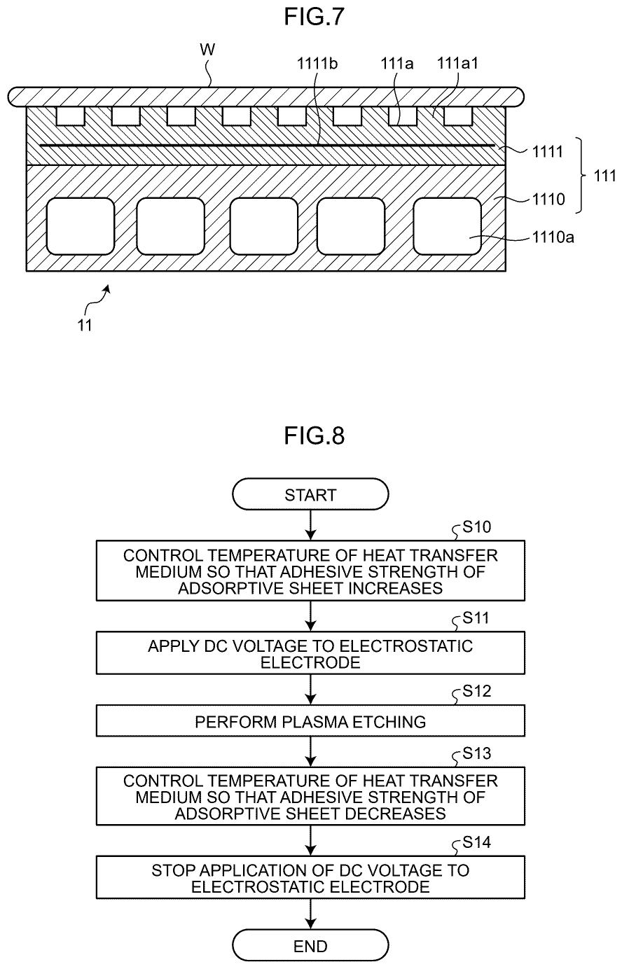

FIG. 7 is a diagram schematically illustrating an example of the configuration of a conventional substrate support 11. FIG. 7 schematically illustrates a configuration of a portion of the substrate support 11 on which the substrate W is placed in the conventional plasma processing apparatus. In the conventional plasma processing apparatus, a plurality of protruding dots 111a1 are formed on an upper surface of the electrostatic chuck 1111. The substrate W is supported on a plurality of dots 111a1 and a space is formed between the substrate W and the electrostatic chuck 1111. In the conventional plasma processing apparatus, helium gas is supplied as a heat transfer gas to the space between the upper surface of the electrostatic chuck 1111 and the substrate W.

However, in the conventional plasma processing apparatus, the supplied helium gas may leak from the periphery of the substrate W and the ring assembly 112, which could affect the plasma processing and incur the risk of electrical discharge. In addition, the conventional plasma processing apparatus requires a gas pipe to supply helium gas to the body 111. Furthermore, in the conventional plasma processing apparatus, the in-plane uniformity of the temperature of the substrate W deteriorates because the thermal resistance of the helium gas portion is different from that of the dot 111a1 portion between the substrate W and the electrostatic chuck 1111. Furthermore, the electrostatic chuck 1111 is hard because it is made of a ceramic member, and its ability to follow the warping of the substrate W is insufficient, resulting in a gap between the electrostatic chuck 1111 and the substrate W, from which helium gas may leak. Furthermore, the substrate W and the ring assembly 112 come into contact with and rub against the electrostatic chuck 1111, which may cause particles.

In contrast, the plasma processing apparatus 1 according to the present embodiment has the adsorptive sheets 120a and 120b between the substrate W and ring assembly 112 and the electrostatic chuck 1111. The plasma processing apparatus 1 according to the present embodiment applies a DC voltage to the electrostatic electrodes 1111b and 1111c to electrostatically clamp the substrate W and the ring assembly 112. As a result, the plasma processing apparatus 1 according to the present embodiment can improve the heat conductivity between the substrate W and ring assembly 112 and the body 111. Since there is no need to supply helium gas between the substrate W and ring assembly 112 and the electrostatic chuck 1111, no helium gas leakage occurs, reducing the risk of electrical discharge. Since the substrate W and ring assembly 112 and the electrostatic chuck 1111 are in surface contact with the adsorptive sheets 120a and 120b, the in-plane uniformity of the temperature of the substrate W and the ring assembly 112 can be improved. Since the substrate W and the ring assembly 112 are disposed on the adsorptive sheets 120a and 120b, the substrate W and the ring assembly 112 can be prevented from coming into contact with the electrostatic chuck 1111, reducing the risk of occurrence of particles.

### [Control Method]

FIG. 8 is a flowchart illustrating an example of a control process flow including processing of a control method according to an embodiment. The processing illustrated in FIG. 8 is implemented by the processing unit 2a1 of the controller 2 reading a computer program from the storage 2a2, executing the read computer program, and controlling each part of the plasma processing apparatus 1 via the communication interface 2a3. The processing illustrated in FIG. 8 is performed, for example, when the substrate W is placed on the central region 111a of the substrate support 11 by a not-illustrated transfer arm and plasma processing is performed in the plasma processing chamber 10.

The controller 2 controls the temperature of the heat transfer medium by the temperature adjusting unit 116 so that the adhesive strength of the adsorptive sheets 120a and 120b increases (S10). For example, the controller 2 controls the temperature of the heat transfer medium supplied from the temperature adjusting unit 116 so that the temperature of the substrate support 11 falls within the second temperature range.

The controller 2 controls the DC power supplies 114a and 114b to apply a DC voltage from the DC power supply 114a to the electrostatic electrode 1111b and apply a DC voltage from the DC power supply 114b to the electrostatic electrode 1111c (S11).

The controller 2 performs plasma etching (S12). For example, the controller 2 controls the exhaust system 40 to evacuate the plasma processing chamber 10 to a predetermined vacuum level. The controller 2 controls the gas supply unit 20 to introduce processing gas for etching from the gas supply unit 20 into the plasma processing space 10s. The controller 2 controls the power supply 30 to supply power from the power supply 30 to generate plasma in the plasma processing chamber 10 and perform etching on the substrate W in accordance with the introduction of processing gas.

When the etching of the substrate W is completed, the controller 2 controls the temperature of the heat transfer medium by the temperature adjusting unit 116 so that the adhesive strength of the adsorptive sheets 120a and 120b decreases (S13). For example, the controller 2 controls the temperature of the heat transfer medium supplied from the temperature adjusting unit 116 so that the temperature of the substrate support 11 falls within the first temperature range.

The controller 2 controls the DC power supplies 114a and 114b to stop the application of a DC voltage from the DC power supplies 114a and 114b to the electrostatic electrodes 1111b and 1111c (S14), and terminates the processing illustrated in this flowchart. After the etching is completed, the substrate W is carried out of the plasma processing apparatus 1 by a not-illustrated transfer arm.

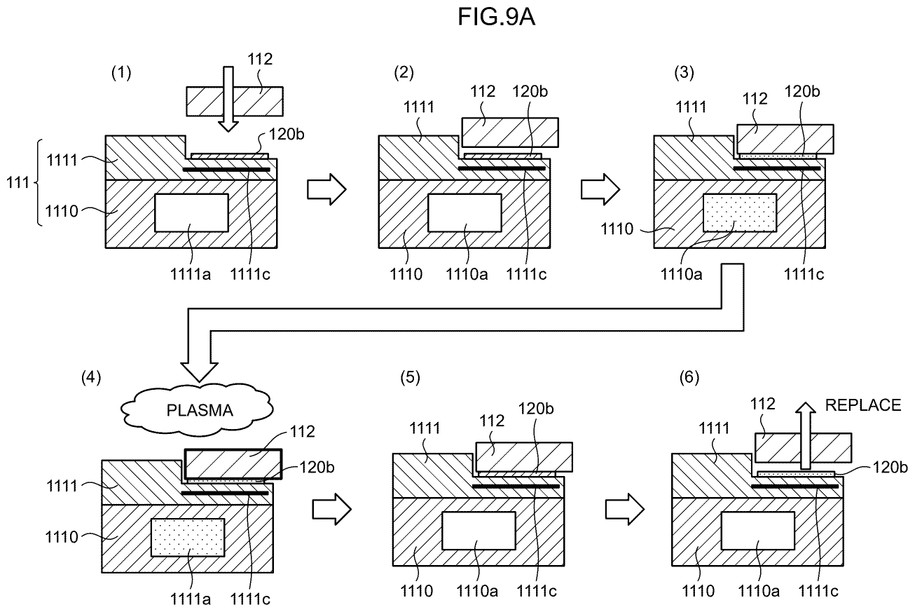

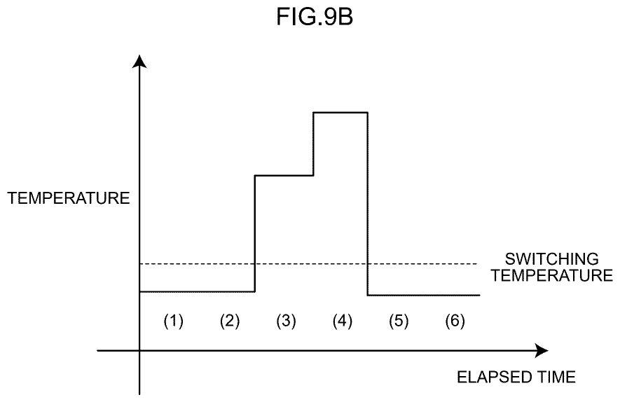

In the above embodiment, the case in which the adsorptive sheets 120a and 120b are disposed in the central region 111a on which the substrate W is placed and in the annular region 111b on which the ring assembly 112 is placed has been described as an example. However, embodiments are not limited to this. The plasma processing apparatus 1 may be configured such that only one of the adsorptive sheets 120a and 120b is disposed. For example, the plasma processing apparatus 1 may have the adsorptive sheet 120b only in the annular region 111b to hold the ring assembly 112. FIG. 9A is a diagram schematically illustrating an example of a flow of holding the ring assembly 112. FIG. 9A illustrates steps for disposing and replacing a new ring assembly 112 as a sequence of steps (1) to (6). FIG. 9B is a graph illustrating an example of temperature change in the adsorptive sheet 120b. FIG. 9B schematically illustrates the temperature change of the adsorptive sheet 120b at steps (1) to (6) in FIG. 9A.

At step (1), the plasma processing chamber 10 is vented and the ring assembly 112 is placed. The controller 2 controls the temperature of the heat transfer medium by the temperature adjusting unit 116 so that the adhesive strength of the adsorptive sheet 120b decreases. For example, at step (1), the temperature of the adsorptive sheet 120b is controlled to fall within the first temperature range below the switching temperature. At step (2), the ring assembly 112 is placed on the adsorptive sheet 120b. At step (2), the temperature of the adsorptive sheet 120b is controlled to fall within the first temperature range. The adsorption of the ring assembly 112 by the adsorptive sheet 120b is weak.

At step (3), the controller 2 controls the temperature of the heat transfer medium by the temperature adjusting unit 116 so that the adhesive strength of the adsorptive sheet 120b increases. For example, at step (3), the temperature of the adsorptive sheet 120b is controlled to fall within the second temperature range above the switching temperature. The controller 2 also controls the DC power supply 114b to apply a DC voltage from the DC power supply 114b to the electrostatic electrode 1111c. Thus, the ring assembly 112 and the adsorptive sheet 120b come into close contact with each other. At step (4), plasma processing is performed. At step (4), the temperature of the adsorptive sheet 120b is controlled to fall within the second temperature range. At step (4), the temperature of the adsorptive sheet 120b becomes higher than at step (3) due to heat input from plasma. At step (4), since the ring assembly 112 and the adsorptive sheet 120b are in close contact with each other, the heat of the ring assembly 112 can diffuse efficiently toward the body 111.

Step (5) is a preparation phase for replacing the ring assembly 112. At step (5), the controller 2 controls the temperature of the heat transfer medium by the temperature adjusting unit 116 so that the adhesive strength of the adsorptive sheet 120b decreases. For example, at step (5), the temperature of the adsorptive sheet 120b is controlled to fall within the first temperature range. The controller 2 also controls the DC power supply 114b to stop the application of a DC voltage from the DC power supply 114b to the electrostatic electrode 1111c. Thus, the adsorption of the ring assembly 112 by the adsorptive sheet 120b is weak. At step (6), the plasma processing chamber 10 is vented and the ring assembly 112 is removed. At step (6), since the adsorption of the ring assembly 112 by the adsorptive sheet 120b is weak, the ring assembly 112 can be easily peeled off from the adsorptive sheet 120b.

In the above embodiment, the case in which the adsorptive sheets 120a and 120b are configured such that the lower surface is bonded to the electrostatic chuck 1111 and the upper surface has adhesive strength increased by changing temperature in a range lower than bonding strength on the lower surface side has been described as an example. However, embodiments are not limited to this. The adsorptive sheet 120a may be configured such that the upper surface is bonded to the substrate W and the lower surface has adhesive strength increased by changing temperature in a range lower than adhesive strength by bonding on the upper surface side. The adsorptive sheet 120b may be configured such that the upper surface is bonded to the ring assembly 112 and the lower surface has adhesive strength increased by changing temperature in a range lower than adhesive strength by bonding on the upper surface side. For example, the adsorptive sheets 120a and 120b each include a plurality of layers, in which a lower surface layer is composed of a cool-off type thermosensitive adhesive sheet and an upper surface layer is a bonding layer having adhesive strength larger than adhesive strength in the second temperature range of the thermosensitive adhesive sheet. In this case, the adsorptive sheets 120a and 120b are attached to and removed from the substrate W and the ring assembly 112 outside the plasma processing apparatus 1. For example, a module of a transfer system that transfers the substrate W is configured to allow attachment and removal of the adsorptive sheet 120a to and from the substrate W.

In the above embodiment, the case in which the electrostatic electrode 1111c is disposed inside the annular region 111b portion of the electrostatic chuck 1111 has been described as an example. However, embodiments are not limited to this. The electrostatic chuck 1111 may be configured without the electrostatic electrode 1111c.

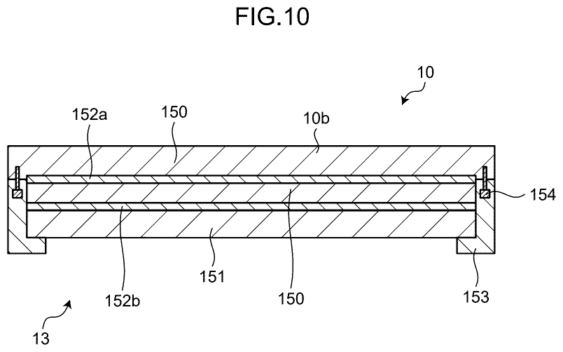

In the above embodiment, the case in which the substrate W and the ring assembly 112 are adsorbed and held by the adsorptive sheets 120a and 120b that change in adhesive strength by changing temperature has been described as an example. However, embodiments are not limited to this. A member of the plasma processing apparatus 1 may be adsorbed and held by an adsorptive sheet that changes in adhesive strength by changing the temperature. For example, an adsorptive sheet may be used to hold the shower head 13. FIG. 10 is a diagram illustrating an example of a schematic configuration around a ceiling at an upper part of the plasma processing chamber 10. FIG. 10 illustrates a ceiling plate 10b that constitutes the upper part of the plasma processing chamber 10. The shower head 13 includes a base plate 150 and a shower plate 151. The base plate 150 is formed of a conductive member in a flat shape and functions as an upper electrode. The shower plate 151 has a not-illustrated gas channel, such as a gas diffusion chamber and a plurality of gas introduction ports, to introduce a processing gas into the plasma processing chamber 10. The base plate 150 is disposed on a lower surface of the ceiling plate 10b. The shower plate 151 is disposed on a lower surface of the base plate 150. A gas channel may also be formed in the base plate 150. For example, a gas diffusion chamber may be formed in the base plate 150, and a hole communicatively connected to the gas diffusion chamber may be formed in the base plate 150, the hole corresponding to each gas introduction port in the shower plate 151. An adsorptive sheet 152a is provided between the ceiling plate 10b and the base plate 150. An adsorptive sheet 152b is provided between the base plate 150 and the shower plate 151. The adsorptive sheets 152a and 152b are configured to change in adhesive strength by changing temperature. For example, the adsorptive sheets 152a and 152b are composed of cool-off type thermosensitive adhesive sheets. The base plate 150 is held by adsorption to the ceiling plate 10b by the adsorptive sheet 152a. The shower plate 151 is held by adsorption to the base plate 150 by the adsorptive sheet 152b. The shower head 13 has its periphery supported by a support 153. The support 153 is secured to the ceiling plate 10b by bolts 154 at a plurality of locations. The temperature of the shower head 13 rises due to heat input from plasma during plasma processing. Thus, the adsorption strength of the adsorptive sheets 152a and 152b increases, and the interface thermal resistance between the base plate 150 and the shower plate 151 and between the ceiling plate 10b and the base plate 150 decreases. As a result, the shower head 13 can efficiently diffuse the heat input from plasma toward the ceiling plate 10b. For example, when maintenance of the shower head 13 is performed, the plasma processing chamber 10 is set to normal temperature equal to or lower than 50° C., the plasma processing chamber 10 is vented, and the shower head 13 is removed. Since the adsorptive sheets 152a and 152b have weak adsorption at normal temperature equal to or lower than 50° C., the shower head 13 can be easily peeled off from the ceiling plate 10b, and the base plate 150 and the shower plate 151 can be easily separated.

An embodiment has been described above. As described above, a substrate processing system according to an embodiment includes the plasma processing chamber 10, the pedestal 1110, a temperature adjuster (the pipes 115 and the temperature adjusting unit 116), the electrostatic chuck 1111, a first electrostatic electrode layer (the electrostatic electrode 1111b), a second electrostatic electrode layer (the electrostatic electrode 1111c), a first power supply (the DC power supply 114a), a second power supply (the DC power supply 114b), and an adsorptive sheet (the adsorptive sheets 120a and 120b). The pedestal 1110 is disposed in the plasma processing chamber 10 and configured such that the flow path 1110a for a heat transfer medium is formed inside. The temperature adjuster is configured to circulate the heat transfer medium through the flow path 1110a and to regulate the temperature of the heat transfer medium. The electrostatic chuck 1111 is disposed on an upper surface of the pedestal 1110 and configured to have a substrate placing portion (the central region 111a portion) on which a substrate W is placed and an edge ring placing portion (the annular region 111b portion) on which an edge ring (the ring assembly 112) surrounding the substrate W is placed. The first electrostatic electrode layer is configured to be disposed in the substrate placing portion. The second electrostatic electrode layer is configured to be disposed in the edge ring placing portion. The first power supply is configured to be electrically connected to the first electrostatic electrode layer. The second power supply is configured to be electrically connected to the second electrostatic electrode layer. The adsorptive sheet is disposed at least one of between the substrate placing portion and the substrate W placed on the substrate placing portion, or between the edge ring placing portion and the edge ring placed on the edge ring placing portion, and is configured to change in adhesive strength by changing temperature. With this configuration, the substrate processing system can improve the heat conductivity between at least one of the substrate W and the edge ring and the placing pedestal.

The substrate processing system according to an embodiment further includes the controller 2. When plasma processing is performed in the plasma processing chamber 10, the controller 2 performs a process including: a step of controlling the temperature of the heat transfer medium by the temperature adjuster so that adhesive strength of the adsorptive sheet increases; and a step of applying a clamping voltage from the first power supply to the first electrostatic electrode layer and applying a clamping voltage from the second power supply to the second electrostatic electrode layer. With this configuration, the substrate processing system according to an embodiment can improve the heat conductivity between at least one of the substrate W and the edge ring and the placing pedestal when performing plasma processing.

The controller 2 performs a process including: a step of controlling the temperature of the heat transfer medium by the temperature adjuster so that adhesive strength of the adsorptive sheet decreases when at least one of the substrate W and the edge ring is replaced; and a step of stopping the application of the clamping voltage from the first power supply to the first electrostatic electrode layer when the substrate is replaced, and stopping the application of the clamping voltage from the second power supply to the second electrostatic electrode layer when the edge ring is replaced. With this configuration, in the substrate processing system according to an embodiment, the substrate W and the edge ring can be easily removed when at least one of the substrate W and the edge ring is replaced.

The adsorptive sheet is configured such that adhesive strength decreases in a first temperature range and adhesive strength increases in a second temperature range above the first temperature range. With this configuration, the substrate processing system according to an embodiment can improve the heat conductivity between at least one of the substrate W and the edge ring and the placing pedestal by setting the adsorptive sheet to the second temperature range. Furthermore, in the substrate processing system according to an embodiment, the substrate W and the edge ring can be easily removed by setting the adsorptive sheet to the first temperature range.

The adsorptive sheet is configured such that adhesive strength increases in a first temperature range and adhesive strength decreases in a second temperature range above the first temperature range. With this configuration, the substrate processing system according to an embodiment can improve the heat conductivity between at least one of the substrate W and the edge ring and the placing pedestal by setting the adsorptive sheet to the first temperature range. Furthermore, in the substrate processing system according to an embodiment, the substrate W and the edge ring can be easily removed by setting the adsorptive sheet to the second temperature range.

The pedestal 1110 is configured such that the flow path 1110a is formed in a region that overlaps at least partially with a region where the adsorptive sheet is disposed in a plan view. With this configuration, in the substrate processing system according to an embodiment, the temperature of the heat transfer medium can be easily transmitted to the adsorptive sheet, and the temperature of the adsorptive sheet can be changed by changing the temperature of the heat transfer medium.

The adsorptive sheet includes a plurality of separate regions. This configuration can reduce a wasted region that cannot be used as an adsorptive sheet when the adsorptive sheet is cut out of a thermosensitive adhesive sheet.

The adsorptive sheet is configured such that a gap between the regions is 2 mm or less. This configuration can reduce the effect of the temperature singularity due to the gap.

The adsorptive sheet (the adsorptive sheet 120b) disposed between the edge ring placing portion and the edge ring is divided into a plurality of arc-shaped regions in a plan view and is configured such that a linear gap is formed between the arc-shaped regions, in which the gap is oriented 30° to 60° relative to the radial direction of the edge ring. This configuration can reduce the effect of the temperature singularity due to the gap.

The adsorptive sheet (the adsorptive sheet 120a) is bonded to the substrate placing portion and is configured such that a surface on the substrate W side changes in adsorption strength by changing temperature in a range lower than bonding strength on the substrate placing portion side. The adsorptive sheet (the adsorptive sheet 120b) is bonded to the edge ring placing portion and is configured such that a surface on the edge ring side changes in adhesive strength by changing temperature in a range lower than adhesive strength on the edge ring placing portion side. With this configuration, the adsorptive sheet can be peeled off on the substrate W side and the edge ring side while being bonded to the substrate placing portion and the edge ring placing portion.

The adsorptive sheet (the adsorptive sheet 120a) is bonded to the substrate W and is configured such that a surface on the substrate placing portion side changes in adhesive strength by changing temperature in a range lower than adhesive strength on the substrate W side. The adsorptive sheet (the adsorptive sheet 120b) is bonded to the edge ring and is configured such that a surface on the edge ring placing portion side changes in adhesive strength by changing temperature in a range lower than adhesive strength on the edge ring side. With this configuration, the adsorptive sheet can be peeled off on the substrate placing portion side and the edge ring placing portion side while being bonded to the substrate W and the edge ring.

The embodiments disclosed herein are exemplary in all respects and should not be construed as limitative. The above embodiments can be embodied in a variety of forms. The foregoing embodiments may be omitted, substituted, or modified in various forms without departing from the scope and spirit of the appended claims.

In the above embodiment, the case in which capacitively coupled plasma (CCP) is used as an example of a plasma source has been described as an example. However, the technology disclosed herein is not limited to this. The plasma source may be, for example, inductively coupled plasma (ICP), microwave excited surface wave plasma (SWP), electron cyclotron resonance plasma (ECP), or helicon wave excited plasma (HWP).

In the above embodiment, the case in which plasma processing such as plasma etching is performed as substrate processing for the substrate W has been described as an example, but embodiments are not limited to this. The substrate processing may be any process that generates heat input to the substrate W. For example, the substrate processing may be a film forming process, a modification process, or a thermal process such as ashing.

In the above embodiment, a plasma processing apparatus for performing plasma processing has been described as an example. However, the technology disclosed herein is not limited to this. The technology disclosed herein may be applied to a substrate processing apparatus that performs substrate processing on the substrate W, such as plasma processing, film forming apparatus, and modification apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

In connection with the above embodiment, the following notes are further disclosed.

### Note 1.

A plasma processing apparatus including:
a plasma processing chamber;
a pedestal disposed in the plasma processing chamber and configured such that a flow path for a heat transfer medium is formed inside;
a temperature adjuster configured to circulate the heat transfer medium through the flow path and to regulate a temperature of the heat transfer medium;
an electrostatic chuck disposed on an upper surface of the pedestal and configured to have a substrate placing portion on which a substrate is placed and an edge ring placing portion on which an edge ring surrounding the substrate is placed;
a first electrostatic electrode layer configured to be disposed in the substrate placing portion;
a second electrostatic electrode layer configured to be disposed in the edge ring placing portion;
a first power supply configured to be electrically connected to the first electrostatic electrode layer;
a second power supply configured to be electrically connected to the second electrostatic electrode layer; and
an adsorptive sheet disposed at least one of between the substrate placing portion and the substrate placed on the substrate placing portion, or between the edge ring placing portion and the edge ring placed on the edge ring placing portion, and configured to change in adhesive strength by changing temperature.

### Note 2.

The plasma processing apparatus according to Note 1, further including a controller, in which
the controller performs a process including:
a step of controlling a temperature of the heat transfer medium by the temperature adjuster so that adhesive strength of the adsorptive sheet increases when plasma processing is performed in the plasma processing chamber; and
a step of applying a clamping voltage from the first power supply to the first electrostatic electrode layer and applying a clamping voltage from the second power supply to the second electrostatic electrode layer.

### Note 3.

The plasma processing apparatus according to Note 2, in which
the controller performs a process including:
a step of controlling a temperature of the heat transfer medium by the temperature adjuster so that adhesive strength of the adsorptive sheet decreases when at least one of the substrate and the edge ring is replaced; and
a step of stopping application of the clamping voltage from the first power supply to the first electrostatic electrode layer when the substrate is replaced, and stopping application of the clamping voltage from the second power supply to the second electrostatic electrode layer when the edge ring is replaced.

### Note 4.

The plasma processing apparatus according to any one of Notes 1 to 3, in which
the adsorptive sheet is configured such that adhesive strength decreases in a first temperature range and adhesive strength increases in a second temperature range above the first temperature range.

### Note 5.

The plasma processing apparatus according to any one of Notes 1 to 3, in which
the adsorptive sheet is configured such that adhesive strength increases in a first temperature range and adhesive strength decreases in a second temperature range above the first temperature range.

### Note 6.

The plasma processing apparatus according to any one of Notes 1 to 5, in which
the pedestal is configured such that the flow path is formed in a region that overlaps at least partially with a region where the adsorptive sheet is disposed in a plan view.

### Note 7.

The plasma processing apparatus according to any one of Notes 1 to 6, in which
the adsorptive sheet includes a plurality of separate regions.

### Note 8.

The plasma processing apparatus according to Note 7, in which
the adsorptive sheet is configured such that a gap between the regions is 2 mm or less.

### Note 9.

The plasma processing apparatus according to Note 7, in which
the adsorptive sheet disposed between the edge ring placing portion and the edge ring is divided into a plurality of arc-shaped regions in a plan view and is configured such that a linear gap is formed between the arc-shaped regions, wherein the gap is oriented 30° to 60° relative to a radial direction of the edge ring.

### Note 10.

The plasma processing apparatus according to any one of Notes 1 to 9, in which
the adsorptive sheet is bonded to the substrate placing portion and configured such that a surface on a side of the substrate changes in adsorption strength by changing temperature in a range lower than bonding strength on a side of the substrate placing portion, or is bonded to the edge ring placing portion and configured such that a surface on a side of the edge ring changes in adhesive strength by changing temperature in a range lower than adhesive strength on a side of the edge ring placing portion.

### Note 11.

The plasma processing apparatus according to any one of Notes 1 to 9, in which
the adsorptive sheet is bonded to the substrate and configured such that a surface on a side of the substrate placing portion changes in adhesive strength by changing temperature in a range lower than adhesive strength on a side of the substrate, or is bonded to the edge ring and configured such that a surface on a side of the edge ring placing portion changes in adhesive strength by changing temperature in a range lower than adhesive strength on a side of the edge ring.

### Note 12.

A control method for a plasma processing apparatus,
the plasma processing apparatus including:
a plasma processing chamber;
a pedestal disposed in the plasma processing chamber and configured such that a flow path for a heat transfer medium is formed inside;
a temperature adjuster configured to circulate the heat transfer medium through the flow path and to regulate a temperature of the heat transfer medium;
an electrostatic chuck disposed on an upper surface of the pedestal and configured to have a substrate placing portion on which a substrate is placed and an edge ring placing portion on which an edge ring surrounding the substrate is placed;
a first electrostatic electrode layer configured to be disposed in the substrate placing portion;
a second electrostatic electrode layer configured to be disposed in the edge ring placing portion;
a first power supply configured to be electrically connected to the first electrostatic electrode layer;
a second power supply configured to be electrically connected to the second electrostatic electrode layer; and
an adsorptive sheet disposed at least one of between the substrate placing portion and the substrate placed on the substrate placing portion, or between the edge ring placing portion and the edge ring placed on the edge ring placing portion, and configured to change in adhesive strength by changing temperature,
the control method comprising:
a step of controlling a temperature of the heat transfer medium by the temperature adjuster so that adhesive strength of the adsorptive sheet increases when plasma processing is performed in the plasma processing chamber; and
a step of applying a clamping voltage from the first power supply to the first electrostatic electrode layer or from the second power supply to the first electrostatic electrode layer.

### REFERENCE SIGNS LIST

1 plasma processing apparatus
2 controller
2a computer
2a1 processing unit
2a2 storage
2a3 communication interface
10 plasma processing chamber
10a side wall
10b ceiling plate
10e gas discharge port
10s plasma processing space
11 substrate support
13 shower head
13a gas supply port
13b gas diffusion chamber
13c gas introduction port
20 gas supply unit
21 gas source
22 flow controller
30 power supply
31 power supply
31a first RF generator
31b second RF generator
32 power supply
32a first DC generator
32a second DC generator
32b second DC generator
40 exhaust system
111 body
111a central region
111a1 dot
111b annular region
112 ring assembly
113a wiring
113b wiring
114a DC power supply
114b DC power supply
115 pipe
116 temperature adjusting unit
120a adsorptive sheet
120b adsorptive sheet
121 sheet
150 base plate
151 shower plate
152a adsorptive sheet
152b adsorptive sheet
153 support
154 bolt
1110 pedestal
1110a flow path
1111 electrostatic chuck
1111a ceramic member
1111b electrostatic electrode
1111c electrostatic electrode
W substrate

1. A plasma processing apparatus comprising:
a plasma processing chamber;
a pedestal disposed in the plasma processing chamber and configured such that a flow path for a heat transfer medium is formed inside;
a temperature adjuster configured to circulate the heat transfer medium through the flow path and to regulate a temperature of the heat transfer medium;
an electrostatic chuck disposed on an upper surface of the pedestal and configured to have a substrate placing portion on which a substrate is placed and an edge ring placing portion on which an edge ring surrounding the substrate is placed;
a first electrostatic electrode layer configured to be disposed in the substrate placing portion;
a second electrostatic electrode layer configured to be disposed in the edge ring placing portion;
a first power supply configured to be electrically connected to the first electrostatic electrode layer;
a second power supply configured to be electrically connected to the second electrostatic electrode layer; and
an adsorptive sheet disposed at least one of between the substrate placing portion and the substrate placed on the substrate placing portion, or between the edge ring placing portion and the edge ring placed on the edge ring placing portion, and configured to change in adhesive strength in response to changing temperature.

2. The plasma processing apparatus according to claim 1, further comprising processing circuitry, wherein
the processing circuitry performs a process including:
a step of controlling a temperature of the heat transfer medium by the temperature adjuster so that adhesive strength of the adsorptive sheet increases when plasma processing is performed in the plasma processing chamber; and
a step of applying a clamping voltage from the first power supply to the first electrostatic electrode layer and applying a clamping voltage from the second power supply to the second electrostatic electrode layer.

3. The plasma processing apparatus according to claim 2, wherein
the processing circuitry performs:
a step of controlling a temperature of the heat transfer medium by the temperature adjuster so that adhesive strength of the adsorptive sheet decreases when at least one of the substrate and the edge ring is replaced; and
a step of stopping application of the clamping voltage from the first power supply to the first electrostatic electrode layer when the substrate is replaced, and stopping application of the clamping voltage from the second power supply to the second electrostatic electrode layer when the edge ring is replaced.

4. The plasma processing apparatus according to claim 1, wherein
the adsorptive sheet is configured such that its adhesive strength decreases in a first temperature range and its adhesive strength increases in a second temperature range above the first temperature range.

5. The plasma processing apparatus according to claim 1, wherein
the adsorptive sheet is configured such that its adhesive strength increases in a first temperature range and its adhesive strength decreases in a second temperature range above the first temperature range.

6. The plasma processing apparatus according to claim 1, wherein
the pedestal is configured such that the flow path is formed in a region that overlaps at least partially with a region where the adsorptive sheet is disposed, when viewed in a plan view.

7. The plasma processing apparatus according to claim 1, wherein
the adsorptive sheet includes a plurality of separate regions.

8. The plasma processing apparatus according to claim 7, wherein
the adsorptive sheet is configured such that a gap between the regions is 2 mm or less.

9. The plasma processing apparatus according to claim 7, wherein
the adsorptive sheet disposed between the edge ring placing portion and the edge ring is divided into a plurality of arc-shaped regions when viewed in a plan view and a linear gap is formed between the arc-shaped regions, and
the gap is oriented 30° to 60° relative to a radial direction of the edge ring.

10. The plasma processing apparatus according to claim 1, wherein
the adsorptive sheet is bonded to the substrate placing portion and a surface on a side of the substrate changes in adsorption strength by changing temperature of the heat transfer medium in a range lower than bonding strength on a side of the substrate placing portion, or the adsorptive sheet is bonded to the edge ring placing portion and a surface on a side of the edge ring changes in adhesive strength by changing temperature of the heat transfer medium in a range lower than adhesive strength on a side of the edge ring placing portion.

11. The plasma processing apparatus according to claim 1, wherein
the adsorptive sheet is bonded to the substrate and is configured such that a surface on a side of the substrate placing portion changes in adhesive strength by changing temperature of the heat transfer medium in a range lower than adhesive strength on a side of the substrate, or is bonded to the edge ring and is configured such that a surface on a side of the edge ring placing portion changes in adhesive strength by changing temperature of the heat transfer medium in a range lower than adhesive strength on a side of the edge ring.

12. A control method for a plasma processing apparatus,
the plasma processing apparatus comprising:
a plasma processing chamber;
a pedestal disposed in the plasma processing chamber and including a flow path for a heat transfer medium;
a temperature adjuster for circulating the heat transfer medium through the flow path and to regulate a temperature of the heat transfer medium;
an electrostatic chuck disposed on an upper surface of the pedestal and including a substrate placing portion on which a substrate is placed and an edge ring placing portion on which an edge ring surrounding the substrate is disposed;
a first electrostatic electrode layer disposed in the substrate placing portion;
a second electrostatic electrode layer disposed in the edge ring placing portion;
a first power supply electrically connected to the first electrostatic electrode layer;
a second power supply electrically connected to the second electrostatic electrode layer; and
an adsorptive sheet disposed at least one of between the substrate placing portion and the substrate placed on the substrate placing portion, or between the edge ring placing portion and the edge ring placed on the edge ring placing portion, and changing in adhesive strength by changing temperature,
the control method comprising:
a step of controlling a temperature of the heat transfer medium by the temperature adjuster so that adhesive strength of the adsorptive sheet increases when plasma processing is performed in the plasma processing chamber; and
a step of applying a clamping voltage from the first power supply to the first electrostatic electrode layer or from the second power supply to the second electrostatic electrode layer.

13. The control method according to claim 12, further comprising:
controlling the temperature of the heat transfer medium by the temperature adjuster so that adhesive strength of the adsorptive sheet decreases; and
stopping application of the clamping voltage from the first power supply to the first electrostatic electrode layer then replacing the substrate.

14. The control method according to claim 12, further comprising:
stopping application of the clamping voltage from the second power supply to the second electrostatic electrode layer when the edge ring is replaced then replacing the edge ring.

15. The control method according to claim 12, wherein
the flow path of the pedestal overlaps at least partially with a region where the adsorptive sheet is disposed, when viewed in a plan view.

16. The control method according to claim 12, wherein
the adsorptive sheet is a first adsorptive sheet among first and second adsorptive sheets,
the first and second adsorptive sheets are separated from one another by a distance greater than 0 mm and less than 2 mm.

17. The control method according to claim 16, wherein
the first adsorptive sheet adsorptive sheet overlaps the substrate placing portion, and
the second adsorptive sheet overlaps the edge ring placing portion.

18. The control method according to claim 17, wherein
the second adsorptive sheet disposed between the edge ring placing portion and the edge ring,
the second adsorptive sheet is divided into a plurality of arc-shaped regions when viewed in a plan view,
a linear gap is formed between the arc-shaped regions, and
the gap is oriented 30° to 60° relative to a radial direction of the edge ring.

19. The control method according to claim 16, further comprising:
replacing the edge ring by controlling the temperature adjuster to change the temperature of the second adsorptive sheet to be within a first temperature range and controlling the second power supply to stop application of a DC voltage to the second electrostatic electrode layer.

20. A plasma processing apparatus comprising:
a plasma processing chamber;
a pedestal disposed in the plasma processing chamber and configured such that a flow path for a heat transfer medium is formed inside;
a temperature adjuster configured to circulate the heat transfer medium through the flow path and to regulate a temperature of the heat transfer medium;
an electrostatic chuck disposed on an upper surface of the pedestal and configured to have a substrate placing portion on which a substrate is placed and an edge ring placing portion on which an edge ring surrounding the substrate is placed;
a first electrostatic electrode layer configured to be disposed in the substrate placing portion;
a second electrostatic electrode layer configured to be disposed in the edge ring placing portion;
a first power supply configured to be electrically connected to the first electrostatic electrode layer;
a second power supply configured to be electrically connected to the second electrostatic electrode layer; and
a first adsorptive sheet disposed between the substrate placing portion and the substrate placed on the substrate placing portion and configured to change in adhesive strength in response to changing temperature; and
a second adsorptive sheet disposed between the edge ring placing portion and the edge ring placed on the edge ring placing portion, and configured to change in adhesive strength in response to changing temperature, the second adsorptive sheet being spaced from the first adsorptive sheet.
